(19) United States
(12) Patent Application Publication
(10) Pub. No.: US 2018/0211988 A1
(43) Pub. Date: Jul. 26, 2018

(54) SOLID STATE IMAGING DEVICE

(71) Applicant: AISIN SEIKI KABUSHIKI KAISHA, Kariya-shi (JP)

(72) Inventor: Takeshi FUJITA, Kitakyushu-shi (JP)

(73) Assignee: AISIN SEIKI KABUSHIKI KAISHA, Kariya-shi (JP)

(21) Appl. No.: 15/877,499

(22) Filed: Jan. 23, 2018

(30) Foreign Application Priority Data
Jan. 26, 2017 (JP) 2017-012462

(51) Int. Cl. H01L 27/146; H04N 9/04; H04N 5/378

(52) U.S. Cl. CPC H01L 27/14609; H04N 9/045; H01L 27/14621; H01L 27/14605; H01L 27/14647; H04N 5/378

(57) ABSTRACT

A solid state imaging device includes: a pixel array unit in which same-color pixels corresponding to each of a plurality of colors configured to convert received light into pixel signals are arranged along a plurality of rows and a plurality of columns; an arithmetic unit configured to read same-color pixel signals from the same-color pixels corresponding to respective same colors and calculate representative values of the plurality of read same-color pixel signals; and an output unit configured to output a set of the calculated representative values to an outside for each of the same colors.

### CROSS REFERENCE TO RELATED APPLICATIONS

This application is based on and claims priority under 35 U.S.C. § 119 to Japanese Patent Application 2017-012462 filed on Jan. 26, 2017, the entire contents of which are incorporated herein by reference.

### TECHNICAL FIELD

This disclosure relates to a solid state imaging device.

### BACKGROUND DISCUSSION

In the related art, there has been known a solid state imaging device which has plural pixels for accumulating signal charges in accordance with received light intensity, sequentially reads the signal charges accumulated in the respective pixels, and outputs the signal charges as image data.

In the solid state imaging device of this type, it is possible to provide an image that appears more natural to the naked eyes by allocating any one of red (R), green (G), and blue (B) to each pixel and combining the signal charges read from the pixels of each color. See, for example, JP 2007-174478 A (Reference 1).

As described above, the solid state imaging device in the related art provides an image suitable for human viewing. Therefore, when an image recognition processing such as face recognition or moving object detection is performed using image data output from the solid state imaging device, an image processing such as a filter processing is performed on the output image data, and an image recognition processing is performed using the image data after the image processing. Thus, the solid state imaging device in the related art has room for further improvement in that the processing load of the image recognition processing is reduced.

### SUMMARY

A solid state imaging device according to an aspect of this disclosure includes, as an example, a pixel array unit in which same-color pixels corresponding to each of a plurality of colors configured to convert received light into pixel signals are arranged along a plurality of rows and a plurality of columns, an arithmetic unit configured to read same-color pixel signals from the same-color pixels corresponding to the respective same colors and calculate representative values of the plurality of read same-color pixel signals, and an output unit configured to output a set of the calculated representative values to an outside for each of the same colors.

### BRIEF DESCRIPTION OF THE DRAWINGS

The foregoing and additional features and characteristics of this disclosure will become more apparent from the following detailed description considered with the reference to the accompanying drawings, wherein:

FIG. 1 is a diagram illustrating an example of a configuration of a CMOS type solid state imaging device according to a first embodiment;

FIG. 2 is a diagram illustrating an example of a filter used for generating edge image data;

FIG. 3 is a diagram illustrating an example of a configuration of a second AD conversion unit;

FIG. 4 is a diagram illustrating an example of a configuration of a column processing unit;

FIG. 5 is a diagram illustrating an example of a configuration of a comparator circuit;

FIG. 6A is a diagram illustrating an exemplary operation of a filter processing according to the first embodiment;

FIG. 6B is a diagram illustrating another exemplary operation of the filter processing according to the first embodiment;

FIG. 7A is a diagram illustrating an exemplary R edge image generated by the filter processing according to the first embodiment;

FIG. 7B is a diagram illustrating another exemplary R edge image generated by the filter processing according to the first embodiment;

FIG. 8 is a diagram illustrating an example of a configuration of pixels according to a second embodiment;

FIG. 9 is a diagram illustrating an example of a configuration of a pixel array unit and an AD conversion unit according to the second embodiment.

FIG. 10A is a diagram illustrating an exemplary operation of a filter processing according to the second embodiment;

FIG. 10B is a diagram illustrating another exemplary operation of the filter processing according to the second embodiment;

FIG. 10C is a diagram illustrating still another exemplary operation of the filter processing according to the second embodiment;

FIG. 10D is a diagram illustrating yet another exemplary operation of the filter processing according to the second embodiment;

FIG. 11A is a diagram illustrating an exemplary R edge image generated by the filter processing according to the second embodiment;

FIG. 11B is a diagram illustrating another exemplary R edge image generated by the filter processing according to the second embodiment;

FIG. 12 is a diagram illustrating an example of a configuration of a solid state imaging device according to a third embodiment; and

FIG. 13 is a block diagram illustrating an example of a configuration of an image recognition system according to the third embodiment.

### DETAILED DESCRIPTION

### First Embodiment

### [1. Configuration of Solid State Imaging Device]

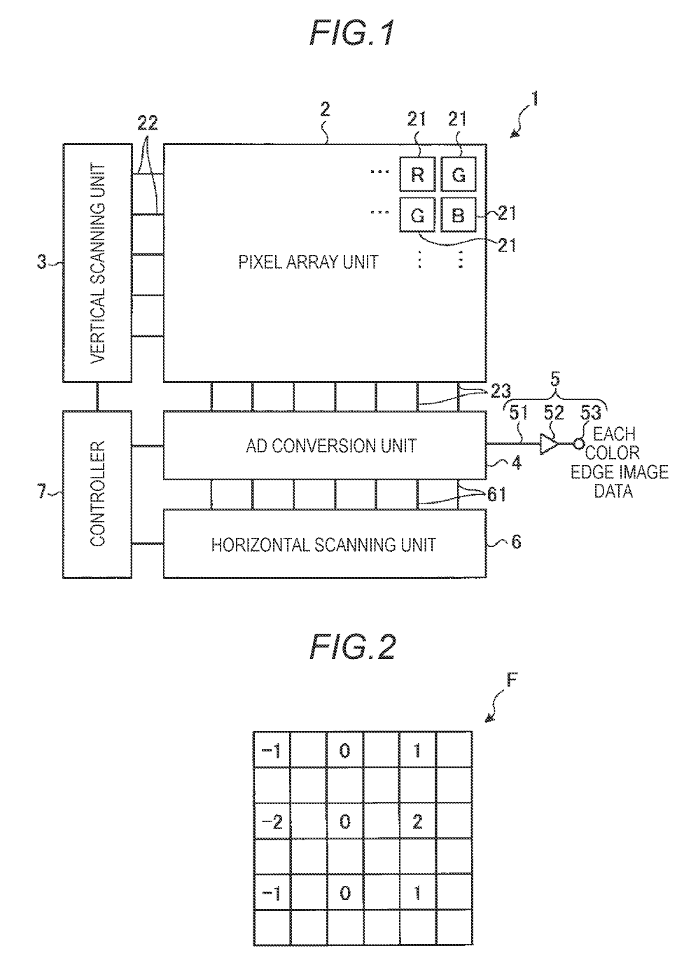

First, a configuration of a solid state imaging device according to a first embodiment will be described with reference to FIGS. 1 and 2. FIG. 1 is a diagram illustrating an example of a configuration of a CMOS type solid state imaging device according to the first embodiment. In addition, FIG. 2 is a diagram illustrating an example of a filter used for generating edge image data. In FIG. 2, a 6×6 filter for extracting edges in the vertical direction is illustrated as an example.

As illustrated in FIG. 1, the solid state imaging device 1 according to the first embodiment performs, for example, a filter processing using a filter F illustrated in FIG. 2 to generate edge image data of red (R), green (G), and blue (B), and outputs the generated edge image data to an external device. The arrangement of the pixels is not limited to the Bayer arrangement illustrated in FIG. 1.

The external device is a recognition device that performs an image recognition processing such as face recognition or moving object detection. The recognition device utilizes edge image data input from the solid state imaging device 1, so that a processing of generating edge images from RAW image data including all of red (R), green (G), and blue (B) may be omitted.

Therefore, according to the solid state imaging device 1, the processing load of the image recognition processing may be reduced.

As illustrated in FIG. 1, the solid state imaging device 1 according to the first embodiment includes a pixel array unit 2, a vertical scanning unit 3, an AD conversion unit 4, an output unit 5, a horizontal scanning unit 6, and a controller 7.

The pixel array unit 2 includes plural pixels 21 arranged in a matrix form along plural rows and plural columns.

Each pixel 21 includes a photodiode, a MOS switch, and the like, and receives any one of color lights separated by a color filter (not illustrated) and converts the received color light into a pixel signal.

Specifically, each pixel 21 receives one of three kinds of color lights of red (R), green (G), and blue (B) to generate a red (R), green (G), or blue (B) pixel signal.

Hereinafter, pixels 21 that receive a color light of the same color among the plural pixels 21 may be referred to as “same-color pixels” in some cases. Further, among the same-color pixels corresponding to each of plural colors arranged in the pixel array unit 2, same-color pixels that receive a red (R) color light may be referred to as “R pixels,” same-color pixels that receive a green (G) color light may be referred to as “G pixels,” and same-color pixels that receive a blue (B) color light may be referred to as “B pixels” in some cases.

Further, in the following descriptions, pixel signals read from the same-color pixels may be referred to as “same-color pixel signals” in some cases. Further, pixel signals read from the R pixels may be referred to as “R pixel signals,” pixel signals read from the G pixels may be referred to as “G pixel signals,” and pixel signals read from the B pixels may be referred to as “B pixel signals” in some cases.

The pixel array unit 2 is provided with plural row selection lines 22, one for each row, and plural vertical signal lines 23, one for each column. The row selection lines 22 connect the plural pixels 21 to the vertical scanning unit 3 row by row. Further, the vertical signal lines 23 connect the plural pixels 21 to the AD conversion unit 4 column by column.

The vertical scanning unit 3 selects a row of pixels 21 from which pixel signals are read, by outputting a row selection pulse to the row selection line 22 under the control of the controller 7.

The AD conversion unit 4 performs an analog-to-digital conversion processing for converting the pixel signals read from the pixel array unit 2 into pixel signals in a digital format.

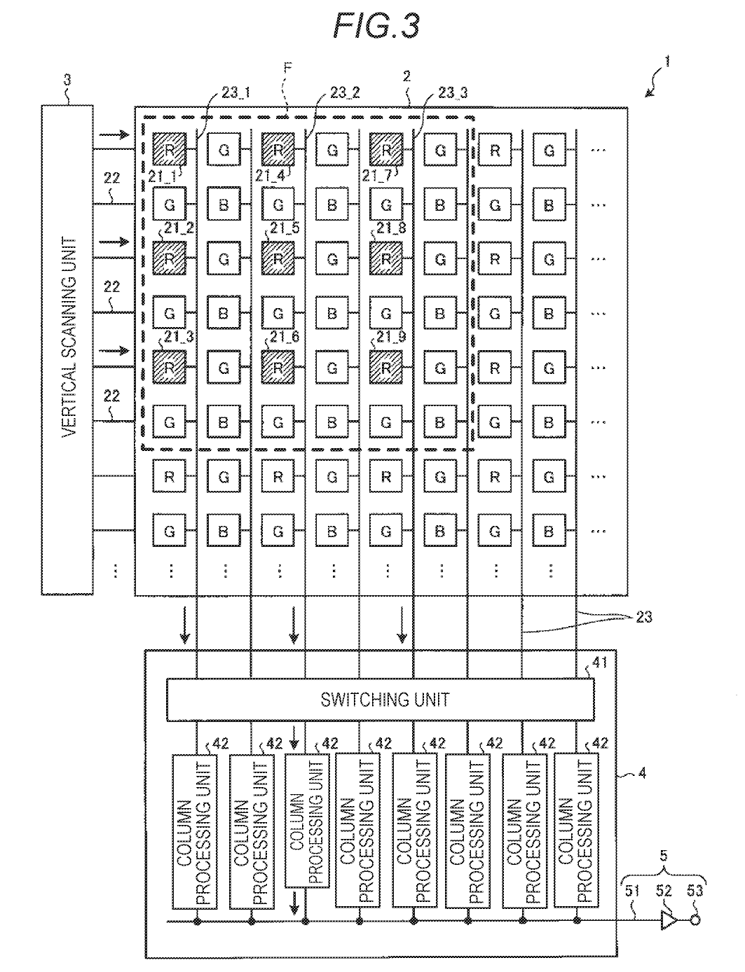

Here, an example of a specific configuration of the AD conversion unit 4 will be described with reference to FIG. 3. FIG. 3 is a diagram illustrating an example of a configuration of the AD conversion unit 4.

As illustrated in FIG. 3, the AD conversion unit 4 includes a switching unit 41 and plural column processing units 42.

The switching unit 41 is provided between the plural vertical signal lines 23 and the plural column processing units 42, and switches a connection state between the plural vertical signal lines 23 and the plural column processing units 42 under the control of the controller 7. As a result, the AD conversion unit 4 may input the same-color pixel signals read from the plural columns to one column processing unit 42.

A single column processing unit 42 is provided for each column of the pixel array unit 2 to perform a filter operation on the input same-color pixel signals. Specifically, the column processing unit 42 performs a multiplication processing and an addition/subtraction processing on the same color pixel signals input thereto.

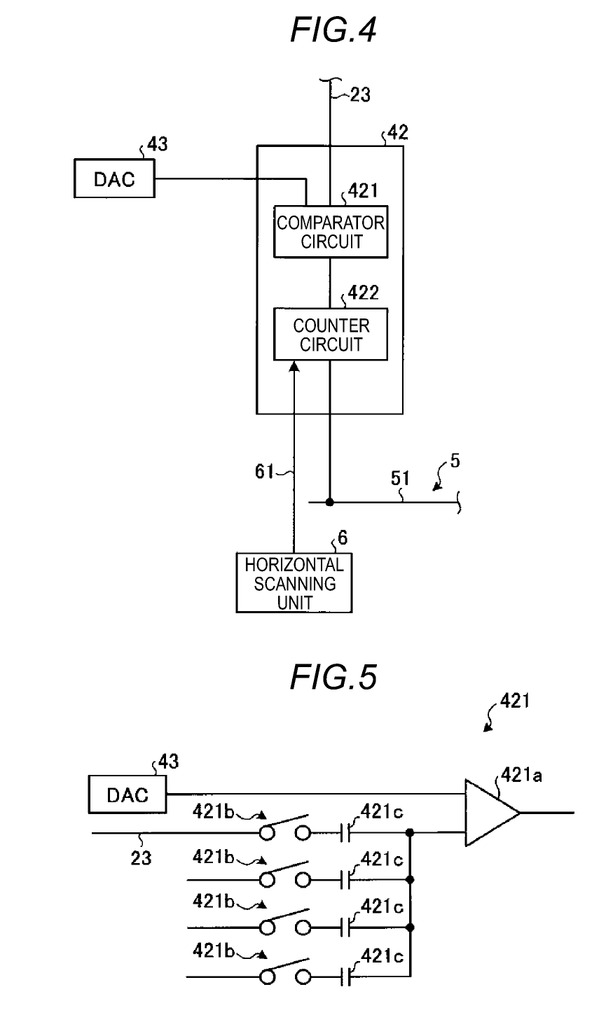

Here, an example of a configuration of the column processing unit 42 will be described with reference to FIGS. 4 and 5. FIG. 4 is a diagram illustrating an example of the configuration of a column processing unit 42. In addition, FIG. 5 is a diagram illustrating an example of a configuration of a comparator circuit.

As illustrated in FIG. 4, the column processing unit 42 includes a comparator circuit 421 and a counter circuit 422.

As illustrated in FIG. 5, the comparator circuit 421 includes, for example, a comparator 421a connected to a digital analog converter (DAC) 43 and a vertical signal line 23. The comparator 421a compares the voltage of a pixel signal input from the vertical signal line 23 with the reference voltage input from the DAC 43, and inverts the output to the counter circuit 422 when the magnitude relationship between the reference voltage and the voltage of the pixel signal is reversed.

The comparator circuit 421 includes plural switches 421b and plural capacitors 421c. The plural switches 421b and the plural capacitors 421c are provided in the vertical signal lines 23 and signal lines connected to the vertical signal lines 23, respectively. The plural switches 421b are controlled by the controller 7.

The counter circuit 422 counts a period of time until the output from the comparator circuit 421 is reversed, and temporarily holds the count value (i.e., pixel data in a digital format) in a latch circuit (not illustrated).

The counter circuit 422 is connected to the horizontal scanning unit 6 via the column selection line 61, and when a column selection pulse is input from the horizontal scanning unit 6 via the column selection line 61, the counter circuit 422 outputs the count value held in the latch circuit (not illustrated) to a horizontal signal line 51 of the output unit 5.

Referring back to FIG. 1, the output unit 5 includes a horizontal signal line 51, an amplification unit 52, and an output terminal 53. The horizontal signal line 51 is connected to the AD conversion unit 4 and transmits pixel data in a digital format output from the AD conversion unit 4. The amplification unit 52 amplifies the pixel data transmitted by the horizontal signal line 51. The output terminal 53 outputs the pixel data amplified by the amplification unit 52 to the outside. A piece of image data is formed by a set of plural pixel data output from the output terminal 53.

The horizontal scanning unit 6 outputs the column selection pulse to the column selection lines 61 under the control of the controller 7 so as to sequentially output the pixel data after the AD conversion processing from the column processing unit 42 provided in the AD conversion unit 4 to the horizontal signal line 51.

The controller 7 includes a clock required for the operation of each unit, a timing generator that supplies a pulse signal at a predetermined timing, and the like, and controls the operation of each of the vertical scanning unit 3, the AD conversion unit 4, the output unit 5, and the horizontal scanning unit 6.

### [2. Operation of Filter Processing]

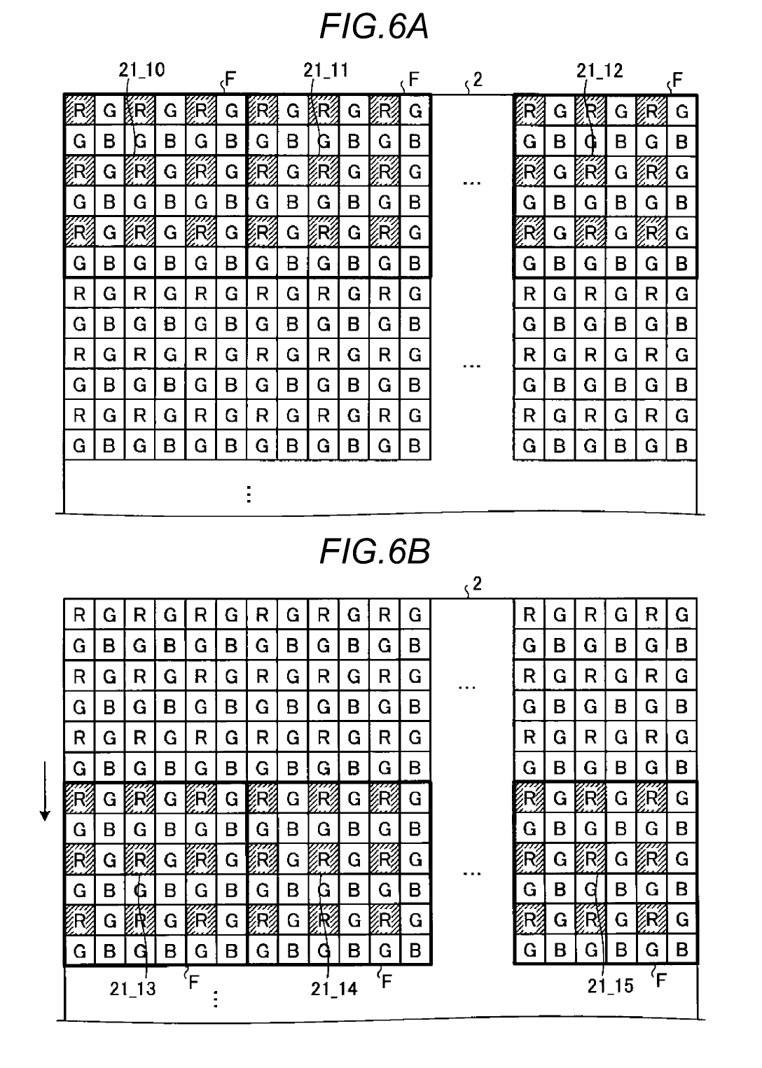

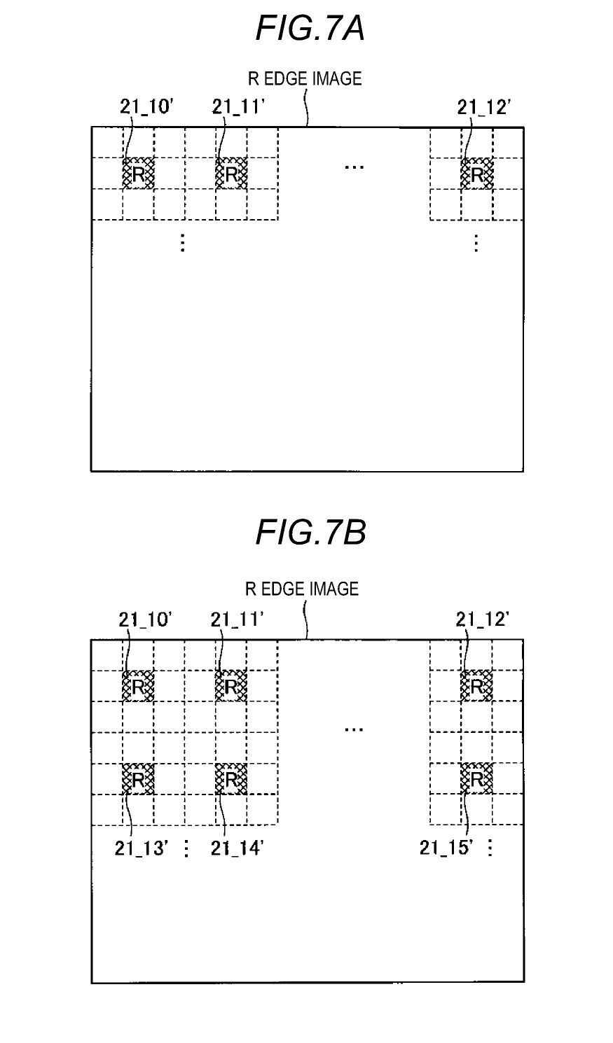

Next, an operation example of the filter processing according to the first embodiment will be described with reference to FIGS. 3, 6A, 6B, 7A, and 7B. FIGS. 6A and 6B are diagrams illustrating operation examples of the filter processing according to the first embodiment. In addition, FIGS. 7A and 7B are diagrams illustrating an exemplary R edge image generated by the filter processing according to the first embodiment.

The solid state imaging device 1 according to the first embodiment performs a processing of obtaining one representative value (pixel data in a digital format) in the filter range by reading the same-color pixel signals from respective same-color pixels included in a filter range of a filter F, and performing a filter operation using the read same-color pixel signals.

Specifically, as illustrated in FIG. 3, the vertical scanning unit 3 selects, from the current filter range, a row in which the pixels 21 for receiving a color light to be filtered (hereinafter, referred to as a “target color light”) are arranged under the control of the controller 7 (see FIG. 1).

For example, in the case illustrated in FIG. 3, the vertical scanning unit 3 sequentially selects three rows in which the nine R pixels 21_1 to 21_9 included in the filter range are arranged, among the plural R pixels 21 that receive red (R) which is the target color light. In addition, the switching unit 41 sequentially connects three vertical signal lines 23_1 to 23_3 connected to the R pixels 21_1 to 21_9 to the column processing unit 42 of the column in which the R pixel 21_5 serving as a filter center is arranged (the third column processing unit 42 from the left), under the control of the controller 7.

As a result, first, the R pixel signals are read from the three R pixels 21_1 to 21_3 connected to the vertical signal line 23_1 among the nine R pixels 21_1 to 21_9, and sequentially input to the column processing unit 42 corresponding to the R pixel 21_5 serving as the filter center.

Subsequently, the column processing unit 42 performs a filter operation using the plural input R pixel signals.

Specifically, in the column processing unit 42, a multiplication processing is performed to multiply the pixel signals of the R pixels 21_1 and 21_3 among the R pixels 21_1 to 21_3 by a filter coefficient “−1” and multiply the pixel signal of the R pixel 21_2 by a filter coefficient “−2.”

The multiplication processing is implemented when each of the R pixel signals of the R pixels 21_1 to 21_3 is appropriately weighted, for example, by switching the connection state of the plural capacitors 421c by controlling the plural switches 421b of the comparator circuit 421.

In addition, in the column processing unit 42, an addition processing is performed to add the R pixel signals after the multiplication processing. The addition processing may be implemented by, for example, a source follower (SF) addition on the vertical signal line 23 connected to the comparator circuit 421.

The multiplication processing and the addition processing are performed on each of the R pixel signals of the R pixels 21_1 to 21_3, so that the calculation results of the R pixels 21_1 to 21_3 (count values) are temporarily held in the counter circuit 422 of the column processing unit 42.

Subsequently, the switching unit 41 connects the vertical signal line 23_2 to the column processing unit 42 of the column in which the R pixel 21_5 serving as the filter center is arranged, and the controller 7 controls the plural switches 421b of the comparator circuit 421, so that the multiplication processing and the addition processing are performed on the R pixel signals of the R pixels 21_4 to 21_6. As a result, in addition to the calculation results on the R pixels 21_1 to 21_3, the calculation results on the R pixels 21_4 to 21_6 are held in the counter circuit 422.

Subsequently, the switching unit 41 connects the vertical signal line 23_3 to the column processing unit 42 of the column in which the R pixel 21_5 serving as the filter center is arranged, and the controller 7 controls the plural switches 421b of the comparator circuit 421, so that the multiplication processing and the addition processing are performed on the R pixel signals of the R pixels 21_7 to 21_9. As a result, the calculation results on the R pixels 21_7 to 21_9 are further held in the counter circuit 422.

Thereafter, the horizontal scanning unit 6 outputs a column selection pulse to the column processing unit 42 of the column in which the R pixel 21_5 serving as the filter center is arranged via the column selection line 61 (see FIG. 1) under the control of the controller 7. As a result, the sum of the calculation results (count values) of the R pixels 21_1 to 21_3, the R pixels 21_4 to 21_6, and the R pixels 21_7 to 21_9, that is, one representative value corresponding to the R pixel 21_5 serving as the filter center is output to the horizontal signal line 51.

In the solid state imaging device 1, the above-described processing, that is, a processing of outputting one representative value for a certain filter range may be performed simultaneously in the horizontal direction by applying plural filters F in the horizontal direction as illustrated in FIG. 6A.

As a result, as illustrated in FIG. 7A, filtered pixel data 21_10′ to 21_12′ corresponding to the R pixels 21_10 to 21_12 each serving as the filter center of each filter F are output from the output unit 5.

Subsequently, the solid state imaging device 1 performs the above-described processing, that is, the process of outputting one representative value for a certain filter range, plural times while changing the position of the filter range.

Specifically, the solid state imaging device 1 shifts the application range of the filter F in the vertical direction by a filter unit (here, 6 pixels) as illustrated in FIG. 6B, and performs the processing of outputting one representative value for each filter range in the same manner as described above.

As a result, as illustrated in FIG. 7B, filtered pixel data 21_13′ to 21_15′ corresponding to the R pixels 21_13 to 21_15 each serving as the filter center of each filter F are output from the output unit 5.

Therefore, the solid state imaging device 1 may generate an R edge image that is an edge image of red (R) that is the target color light, by repeatedly performing the filter calculation while shifting the filter F by a filter unit.

In addition, the solid state imaging device 1 may sequentially output edge images of other color lights by repeatedly performing the same processing using another color light as a target color light. For green (G), each of an edge image of the G pixels 21 arranged in the same row as the R pixels 21 and an edge image of the G pixels 21 arranged in the same row as the B pixels 21 may be generated and output.

As described above, the solid state imaging device 1 according to the first embodiment includes the pixel array unit 2, the vertical scanning unit 3, the AD conversion unit 4 (an example of the calculation unit), and the output unit 5. In the pixel array unit 2, the same-color pixels 21 corresponding to each of plural colors that convert the received light into pixel signals are arranged along plural rows and plural columns. The vertical scanning unit 3 and the AD conversion unit 4 individually read the same-color pixel signals from the same-color pixels 21 of the same color and calculate representative values of the plural read same-color pixel signals. The output unit 5 outputs a set of representative values calculated by the AD conversion unit 4 to the outside for each of the same colors.

Thus, according to the solid state imaging device 1 of the first embodiment, the processing load of the image recognition processing may be reduced.

### Second Embodiment

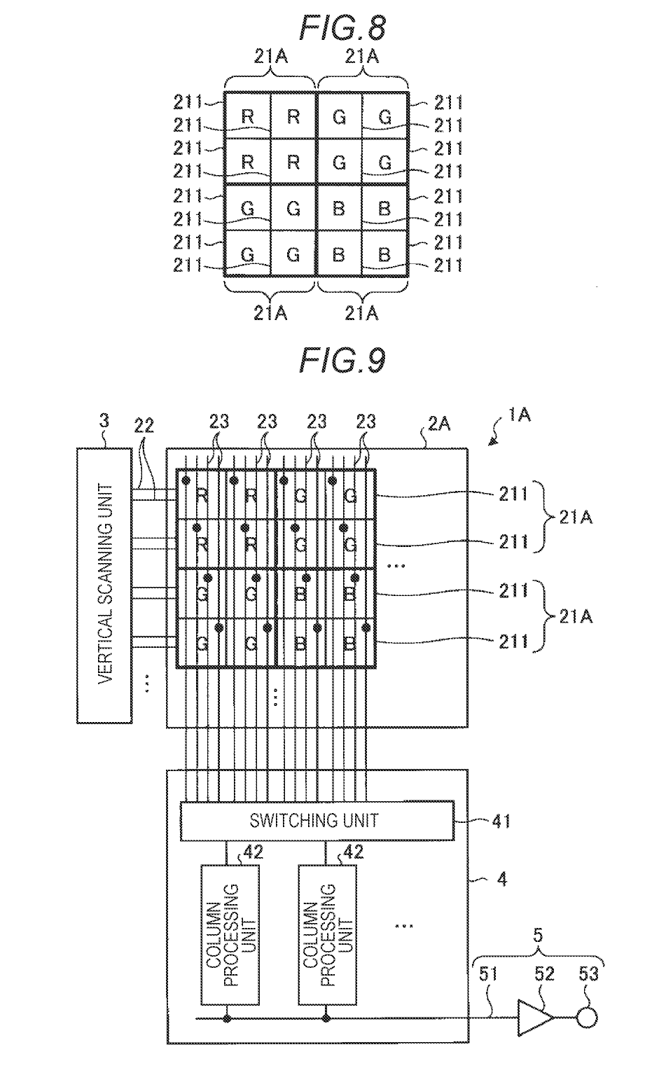

Next, a solid state imaging device according to a second embodiment will be described. FIG. 8 is a diagram illustrating an example of a configuration of pixels according to a second embodiment.

As illustrated in FIG. 8, each of plural pixels 21A according to the second embodiment includes plural divided pixels 211. For example, in the case illustrated in FIG. 8, an R pixel 21A includes 2×2 R divided pixels 211, a G pixel 21A has 2×2 G divided pixels 211, and a B pixel 21A includes 2×2 B divided pixels 211.

As described above, since the pixels 21A, each including plural divided pixels 211, are provided, it is possible to read a pixel signal from one pixel 21A plural times.

Here, an example in which one pixel 21A is divided into four divided pixels 211 is illustrated, but the number of divisions of the pixel 21A is not limited to four.

FIG. 9 is a diagram illustrating an example of a configuration of a pixel array unit and an AD conversion unit according to the second embodiment. In the following descriptions, the same parts as those already described are denoted by the same reference numerals as those already described, and redundant descriptions thereof will be omitted.

As illustrated in FIG. 9, plural row selection lines 22 and plural vertical signal lines 23 are provided in a pixel array unit 2A, and each division pixel 211 is connected to any one of the row selection line 22 and any one of the vertical signal lines 23, respectively. Thus, it is possible to read the pixel signals individually from the plural divided pixels 211 included in one pixel 21A.

The numbers of the row selection lines 22 and the vertical signal lines 23 provided in the pixel array section 2A are not limited to those illustrated in the drawing, and other configurations may be adopted as long as the pixel signals are capable of being individually read from the plural divided pixels 211 included in one pixel 21A.

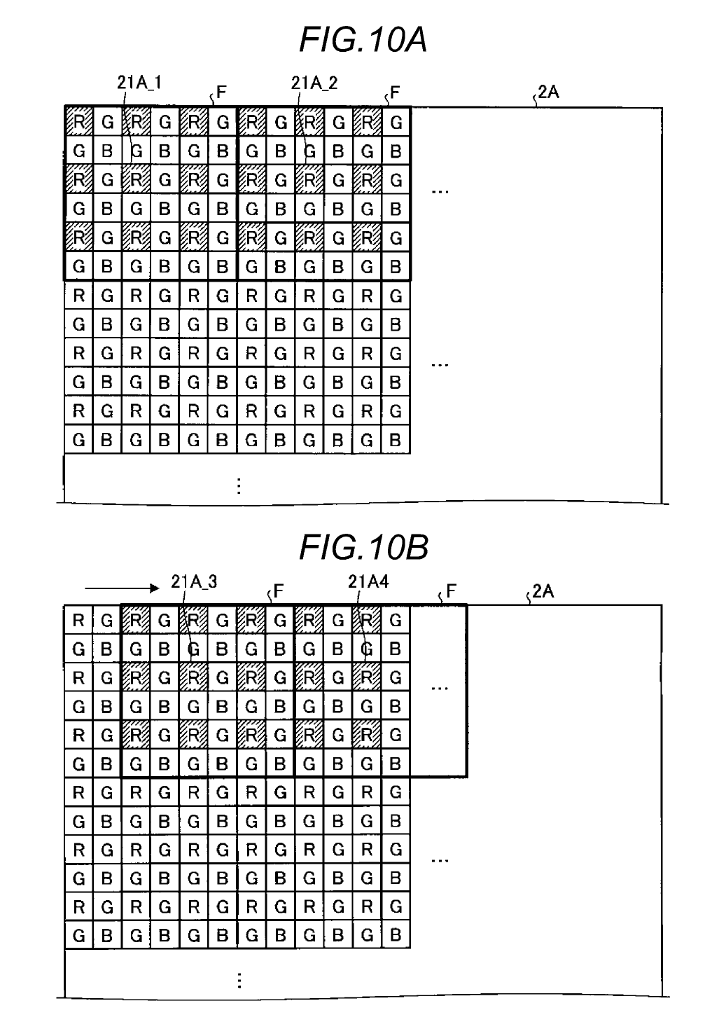

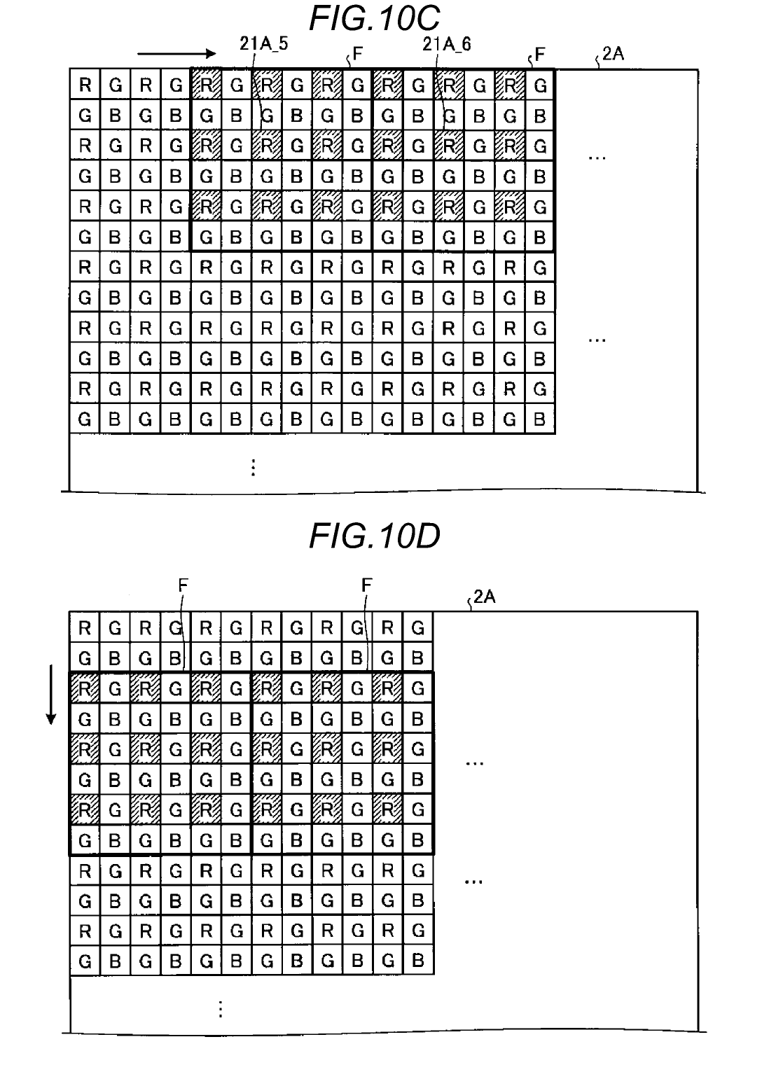

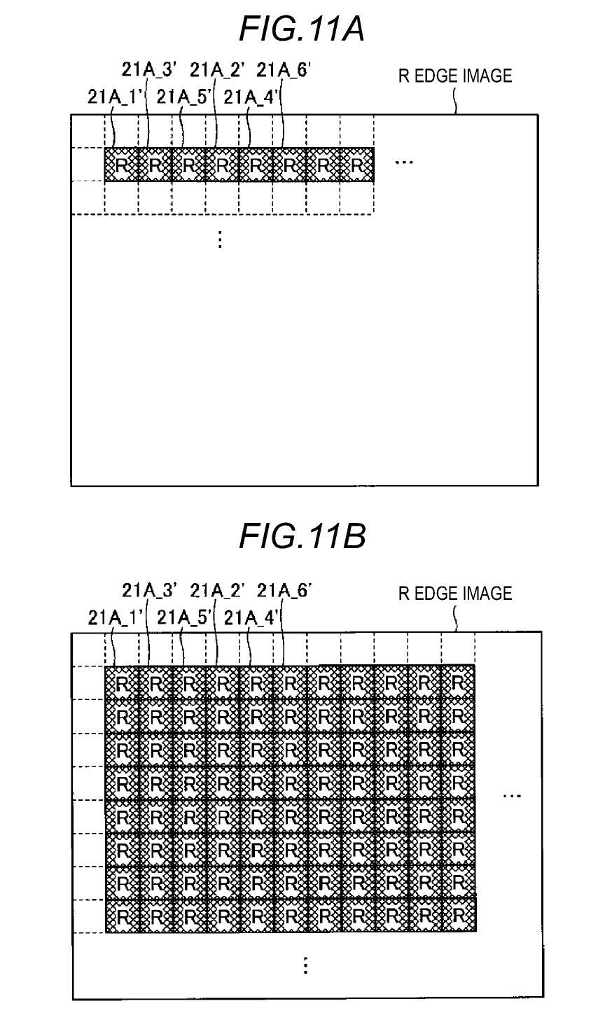

Next, the filtering operation according to the second embodiment will be described with reference to FIGS. 10A to 10D, 11A, and 11B. FIGS. 10A to 10D are diagrams illustrating an exemplary operation of the filter processing according to the second embodiment. In addition, FIGS. 11A and 11B are diagrams illustrating an exemplary R edge image generated by the filter processing according to the second embodiment.

As illustrated in FIG. 10A, the solid state imaging device 1A according to the second embodiment performs the first filter operation by applying plural filters F in the horizontal direction. Specifically, the solid state imaging device 1A reads a pixel signal from any one of plural divided pixels 211 included in each pixel 21A and performs the first filtering processing.

Subsequently, as illustrated in FIG. 10B, the solid state imaging device 1A performs the second filtering processing by shifting the position of the filter F by one pixel in the horizontal direction. At this time, the solid state imaging device 1A reads a pixel signal from a divided pixel 211 different from the divided pixel 211 from which the pixel signal is read in the first filtering processing.

Subsequently, as illustrated in FIG. 100, the solid state imaging device 1A performs the third filtering processing by shifting the position of the filter F by one pixel in the horizontal direction. At this time, the solid state imaging device 1A reads a pixel signal from a divided pixel 211 different from the divided pixels 211 from which the pixel signals were read in the first and second filtering processings.

As a result, as illustrated in FIG. 11A, filtered pixel data 21A_1′ to 21A_6′ corresponding to the R pixels 21A_1 to 21A_6 . . . each serving as the filter center of each filter F are output from the output unit 5.

Thereafter, as illustrated in FIG. 10D, the solid state imaging device 1A repeats the same processing as those in FIGS. 10A to 10C while shifting the position of the filters F by one pixel in the vertical direction. As a result, as illustrated in FIG. 11B, it is possible to generate an R edge image having a larger information amount than the R edge image generated in the solid state imaging device 1 according to the first embodiment (see FIG. 7B).

As described above, in the solid state imaging device 1A according to the second embodiment, each of the same-color pixels includes plural divided pixels, and the vertical scanning unit 3 and the AD conversion unit 4 read the same-color pixel signal plural times from one same-color pixel 21A while changing the divided pixels 211 to be read. Therefore, according to the solid state imaging device 1A of the second embodiment, it is possible to increase an information amount of the image data after the filter processing, as compared with a case where the filter processing is performed by reading a same-color pixel signal only once from one same-color pixel as in the first embodiment.

### Third Embodiment

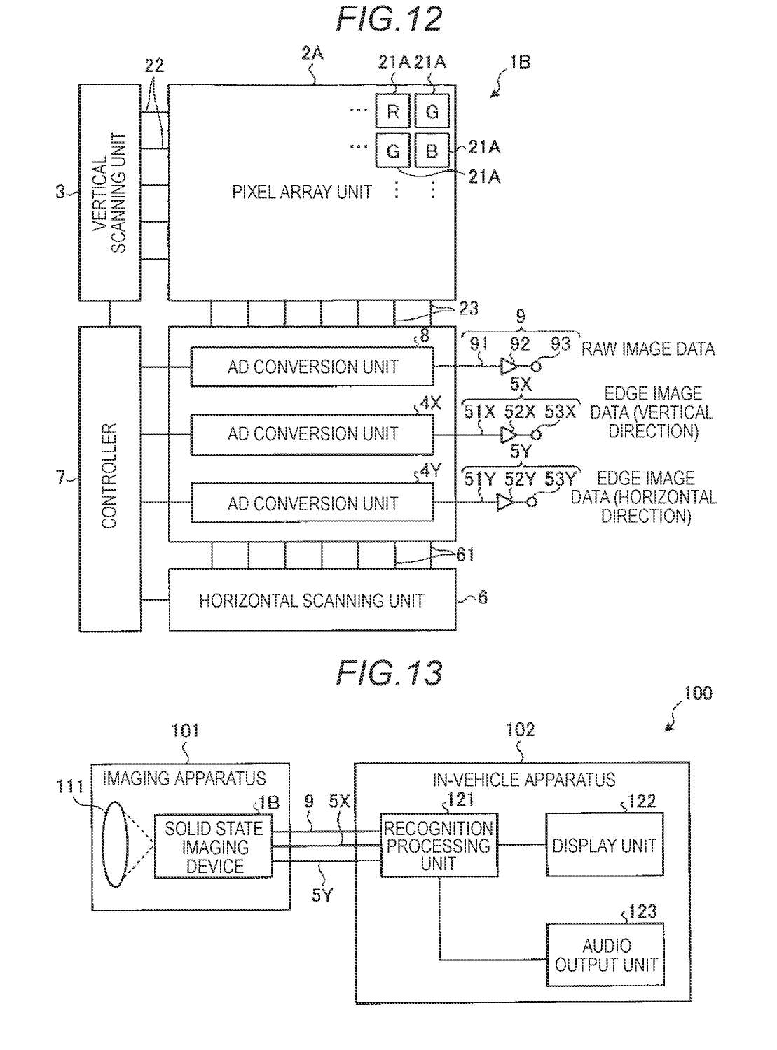

Next, a solid state imaging device according to a third embodiment will be described with reference to FIG. 12. FIG. 12 is a diagram illustrating an example of a configuration of a solid state imaging device according to a third embodiment.

As illustrated in FIG. 12, a solid state imaging device 1B according to the third embodiment may output plural types of pixel data at the same time. For example, the solid state imaging device 1B may output the pixel data of the edge image in the vertical direction, the pixel data of the edge image in the horizontal direction, and the pixel data of the RAW image at the same time.

The solid state imaging device 1B includes, for example, the pixel array unit 2A according to the second embodiment, a vertical scanning unit 3, plural AD conversion units 4X, 4Y, and 8, plural output units 5X, 5Y, and 9, a horizontal scanning unit 6, and a controller 7.

Each of the plural AD conversion units 4X, 4Y, and 8 is connected to the plural vertical signal lines 23, the plural column selection lines 61, and the controller 7. Further, the AD conversion unit 4X is connected to the output unit 5X, the AD conversion unit 4Y is connected to the output unit 5Y, and the AD conversion unit 8 is connected to the output unit 9.

The AD conversion unit 8 includes, for example, a column processing unit (not illustrated) which is provided for each column in the pixel array unit 2A. Each column processing unit performs AD conversion processing on a pixel signal input from one of the divided pixels 211 of each pixel 21A arranged in the reading row selected by the vertical scanning section 3 via the vertical signal line 23.

The output unit 9 includes a horizontal signal line 91, an amplification unit 92, and an output terminal 93. The horizontal signal line 91 is connected to the AD conversion unit 8 and transmits pixel data in a digital format output from the AD conversion unit 8. The amplification unit 92 amplifies the pixel data transmitted by the horizontal signal line 91. The output terminal 93 outputs the pixel data amplified by the amplification unit 92 to the outside.

The solid state imaging device 1B generates pixel data of the RAW image using the pixel array unit 2A, the vertical scanning unit 3, the AD conversion unit 8, the horizontal scanning unit 6, and the controller 7, and outputs the pixel data from the output unit 9.

Specifically, the vertical scanning section 3 outputs a row selection pulse to any one of the plural row selection lines 22, and the AD conversion section 8 converts the pixel signals of the selected one row into pixel data in a digital format for each column. Subsequently, in the solid state imaging device 1B, the horizontal scanning unit 6 outputs the pixel data after the AD conversion processing to, for example, the horizontal signal line 91 for each of red (R), green (G), and blue (B). As a result, the pixel data of the RAW image for one row is output to the outside. Then, pixel data of the RAW image for one frame may be output by repeating the same processings while shifting the row selected by the vertical scanning unit 3 in the vertical direction.

The configurations of the AD conversion units 4X and 4Y and the output units 5X and 5Y are the same as those of the AD conversion unit 4 and the output unit 5 described above. Therefore, the descriptions here will be omitted.

The solid state imaging device 1B generates an edge image in the vertical direction for each of the same colors using the pixel array unit 2A, the vertical scanning unit 3, the AD conversion unit 4X, the horizontal scanning unit 6, and the controller 7, and outputs the edge image from the output unit 5X. The operation of the filtering processing in the case of generating the edge image in the vertical direction is the same as that already described with reference to FIG. 3 in the first embodiment.

Further, the solid state imaging device 1B generates an edge image in the horizontal direction for each of the same colors using the pixel array unit 2A, the vertical scanning unit 3, the AD conversion unit 4Y, the horizontal scanning unit 6, and the controller 7, and outputs the edge image from the output unit 5Y.

Here, an operation example in the case of generating an edge image in the horizontal direction will be described with reference to FIG. 3.

First, the vertical scanning unit 3 selects a row in which the R pixels 21_1, 21_4, and 21_7 are arranged under the control of the controller 7. Subsequently, under the control of the control unit 7, the switching unit 41 switches the connection state between the plural vertical signal lines 23 and the plural column processing units 42 such that the R pixel signals of the R pixels 21_1, 21_4, and 21_7 are sequentially input to a column processing unit 42 corresponding to the column in which the R pixel 21_5 serving as the filter center is arranged. Subsequently, the column processing unit 42 performs a multiplication processing and an addition processing on the R pixel signals sequentially input from the vertical signal line 23 under the control of the control unit 7. As a result, calculation results (count values) for the R pixels 21_1, 21_4, and 21_7 are temporarily held in the counter circuit 422 of the column processing unit 42.

Subsequently, the vertical scanning unit 3 selects a row in which the R pixels 21_2, 21_5, and 21_8 are arranged under the control of the controller 7. Subsequently, under the control of the control unit 7, the switching unit 41 switches the connection state between the plural vertical signal lines 23 and the plural column processing units 42 such that the R pixel signals of the R pixels 21_2, 21_5, and 21_8 are sequentially input to a column processing unit 42 corresponding to the column in which the R pixel 21_5 serving as the filter center is arranged. Subsequently, the column processing unit 42 performs a multiplication processing and an addition processing on the R pixel signals sequentially input from the vertical signal line 23 under the control of the control unit 7. As a result, calculation results (count values) for the R pixels 21_2, 21_5, and 21_8 are further held in the counter circuit 422 of the column processing unit 42.

Subsequently, the vertical scanning unit 3 selects a row in which the R pixels 21_3, 21_6, and 21_9 are arranged under the control of the controller 7. Subsequently, under the control of the control unit 7, the switching unit 41 switches the connection state between the plural vertical signal lines 23 and the plural column processing units 42 such that the R pixel signals of the R pixels 21_3, 21_6, and 21_9 are sequentially input to a column processing unit 42 corresponding to the column in which the R pixel 21_5 serving as the filter center is arranged. Subsequently, the column processing unit 42 performs a multiplication processing and an addition processing on the R pixel signals sequentially input from the vertical signal line 23 under the control of the control unit 7. As a result, calculation results (count values) for the R pixels 21_3, 21_6, and 21_9 are further held in the counter circuit 422 of the column processing unit 42.

Thereafter, the horizontal scanning unit 6 outputs a column selection pulse to the column processing unit 42 corresponding to the column in which the R pixel 21_5 serving as the filter center is arranged via the column selection line 61 under the control of the controller 7. As a result, the sum of the calculation results (count values) of the R pixels 21_1, 21_4, and 21_7, the R pixels 21_2, 21_5, and 21_8, and the R pixels 21_3, 21_6, and 21_9, that is, one representative value corresponding to the R pixel 21_5 serving as the filter center is output to the horizontal signal line 51Y. The R edge image in the horizontal direction may be generated by performing the above-described processings plural times while shifting the target pixel serving as the filter center.

As described above, the solid state imaging device 1B according to the third embodiment may output plural types of pixel data to the outside.

The solid state imaging device 1B may provide more types of image data by increasing the number of sets of the AD conversion unit and the output unit.

For example, the solid state imaging device 1B may output image data, which is resized to a predetermined size, to the outside. In this case, the solid state imaging device 1B may output, for example, image data thinned by ⅓ in the vertical direction and image data thinned by ⅕ in the vertical direction at the same time by increasing the number of sets of the AD conversion unit and the output unit by two sets and performing a resizing processing using different pixels.

### Fourth Embodiment

Next, an exemplary case where the solid state imaging device 1B according to the third embodiment is applied to an in-vehicle image recognition system will be described with reference to FIG. 13. FIG. 13 is a block diagram illustrating an example of a configuration of an image recognition system according to a fourth embodiment.

An image recognition system 100 illustrated in FIG. 13 includes an imaging apparatus 101 and an in-vehicle apparatus 102. The imaging apparatus 101 is provided outside the vehicle, and the in-vehicle apparatus 102 is provided inside the vehicle.

The imaging apparatus 101 is provided at any one of, for example, the front, the rear, and the side of the vehicle. The imaging apparatus 101 includes a solid state imaging device 1B and an optical system 111 that guides incident light from a subject to the solid state imaging device 1B. The optical system 111 includes, for example, a microlens that collects incident light and a color filter that separates incident light into red (R), green (G), and blue (B) components.

The in-vehicle apparatus 102 is provided at a predetermined position inside the vehicle such as a dashboard. The in-vehicle apparatus 102 includes a recognition processing unit 121, a display unit 122, and an audio output unit 123. The display unit 122 is, for example, a liquid crystal display (LCD), an organic electro-luminescence display (OELD), or the like. The audio output unit 123 is, for example, a speaker.

The recognition processing unit 121 is connected to output units 5X, 5Y, and 9 of the solid state imaging device 1B, and performs an image recognition processing such as face recognition or moving object detection using edge images in the vertical direction and the horizontal direction input from the output units 5X and 5Y. Then, the recognition processing unit 121 displays information on the display unit 122 or outputs audio from the audio output unit 123 according to the result of the image recognition processing.

For example, when a moving object is detected by the image recognition processing, the recognition processing unit 121 uses RAW image data input from the output unit 9 to generate an image in which a frame image is superimposed around the detected moving object and displays the image on the display unit 122. Thus, the presence of a pedestrian or the like may be recognized by the driver.

As described above, according to the image recognition system 100 according to the fourth embodiment, the processing load of the recognition processing unit 121 may be reduced by using the solid state imaging device 1B that outputs an edge image.

Here, an example in which the solid state imaging device 1B according to the third embodiment is used has been described, but the solid-state imaging device 1 according to the first embodiment or the solid state imaging device 1A according to the second embodiment may be used instead of the solid state imaging device 1B.

In each of the above-described embodiments, an example of performing an edge extraction processing using an edge filter has been described as an example of the filter processing, but the filter processing may be a processing other than the edge extraction processing, for example, a smoothing processing using a smoothing filter.

A solid state imaging device according to an aspect of this disclosure includes, as an example, a pixel array unit in which same-color pixels corresponding to each of a plurality of colors configured to convert received light into pixel signals are arranged along a plurality of rows and a plurality of columns, an arithmetic unit configured to read same-color pixel signals from the same-color pixels corresponding to the respective same colors and calculate representative values of the plurality of read same-color pixel signals, and an output unit configured to output a set of the calculated representative values to an outside for each of the same colors. Therefore, as an example, it is possible to omit an image processing for generating image data for an image recognition processing in an external recognition device. Thus, according to the solid state imaging device of the embodiment, the processing load of the image recognition processing may be reduced.

In the solid state imaging device, as an example, the arithmetic unit performs a processing in which the same-color pixel signals are read from the same-color pixels included in a filter range of two or more of the rows and two or more of the columns, and one of the representative values in the filter range is obtained by performing a filter operation using the same-color pixel signal, a plurality of times while changing a position of the filter range. Therefore, as an example, it is possible to provide image data for each color, which is subjected to a filter processing such as an edge extraction to the outside.

In the solid state imaging device, as an example, the arithmetic unit includes a plurality of vertical signal lines provided corresponding to the plurality of columns and configured to transmit the same-color pixel signals read from the same-color pixels, a plurality of column processing units provided corresponding to the plurality of columns and configured to perform the filter operation on the input same-color pixel signals, and a switching unit provided between the plurality of vertical signal lines and the plurality of column processing units and configured to switch a connection state between the plurality of vertical signal lines and the plurality of column processing units to input the same-color pixel signals to one of the column processing units. Therefore, as an example, when providing the switching unit, it is possible to reduce the number of required column processing units.

In the above-described solid state imaging device, as an example, the column processing unit performs the filter operation using a comparator circuit used for an analog-to-digital conversion processing and a counter circuit. Therefore, as an example, it is possible to implement a filter operation with a relatively simple configuration without separately providing a memory or the like for the filter operation.

In the above-described solid state imaging device, as an example, each of the same-color pixels includes a plurality of divided pixels, and the arithmetic unit reads the same-color pixel signals from one of the same-color pixels a plurality of times while changing the divided pixels to be read. Therefore, as an example, it is possible to increase an information amount of the image data after the filter processing, as compared with a case where a filter processing is performed by reading the same-color pixel signals only once from one of the same-color pixels.

Although the embodiments of this disclosure are exemplified above, the above-described embodiments and modifications are merely illustrative, and it is not intended to limit the scope of the invention. The above-described embodiment and modifications may be implemented in various other modes, and various omissions, substitutions, combinations, and changes may be made without departing from the gist of the invention. Further, the configurations and shapes of the respective embodiments and modifications may be partially replaced and implemented.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A solid state imaging device comprising:
a pixel array unit in which same-color pixels corresponding to each of a plurality of colors configured to convert received light into pixel signals are arranged along a plurality of rows and a plurality of columns;
an arithmetic unit configured to read same-color pixel signals from the same-color pixels corresponding to respective same colors and calculate representative values of the plurality of read same-color pixel signals; and
an output unit configured to output a set of the calculated representative values to an outside for each of the same colors.

2. The solid state imaging device according to claim 1,
wherein the arithmetic unit performs a processing in which the same-color pixel signals are read from the same-color pixels included in a filter range of two or more of the rows and two or more of the columns, and one of the representative values in the filter range is obtained by performing a filter operation using the same-color pixel signal, a plurality of times while changing a position of the filter range.

3. The solid state imaging device according to claim 2,
wherein the arithmetic unit includes:
a plurality of vertical signal lines provided corresponding to the plurality of columns and configured to transmit the same-color pixel signals read from the same-color pixels;
a plurality of column processing units provided corresponding to the plurality of columns and configured to perform the filter operation on the input same-color pixel signals; and
a switching unit provided between the plurality of vertical signal lines and the plurality of column processing units and configured to switch a connection state between the plurality of vertical signal lines and the plurality of column processing units to input the same-color pixel signals to one of the column processing units.

4. The solid state imaging device according to claim 3,
wherein the column processing unit performs the filter operation using a comparator circuit used for an analog-to-digital conversion processing and a counter circuit.

5. The solid state imaging device according to claim 1,
wherein each of the same-color pixels includes a plurality of divided pixels, and
the arithmetic unit reads the same-color pixel signals from one of the same-color pixels a plurality of times while changing the divided pixels to be read.
